(19) United States
(12) Patent Application Publication
(10) Pub. No.: US 2013/0307012 A1
(43) Pub. Date: Nov. 21, 2013

(54) TENSION RELEASE LAYER STRUCTURE OF LIGHT-EMITTING DIODE

(71) Applicants: Li-Ping Chou, Taichung City (TW); Wei-Yu Yen, Taichung City (TW); Fu-Bang Chen, Taichung City (TW); Chih-Sung Chang, Taichung City (TW)

(72) Inventors: Li-Ping Chou, Taichung City (TW); Wei-Yu Yen, Taichung City (TW); Fu-Bang Chen, Taichung City (TW); Chih-Sung Chang, Taichung City (TW)

(73) Assignee: HIGH POWER OPTO, INC.

(21) Appl. No.: 13/472,141

(22) Filed: May 15, 2012

(51) Int. Cl. H01L 33/62

(52) U.S. Cl. 257/99; 257/E33.062

(57) ABSTRACT

A tension release layer structure is applied to an LED which includes a P-type electrode, a permanent substrate, a binding layer, a tension release layer, a mirror layer, a P-type semiconductor layer, a light-emitting layer, an N-type semiconductor layer and an N-type electrode that are stacked in sequence. The tension release layer is made of a complex material including at least two material elements with boundaries that are blended with each other. As the complex material in the tension release layer does not have apparent interface separation, stress between interface effect and materials can be eliminated to increase light-emitting efficiency and production yield of the LED.

### FIELD OF THE INVENTION

The present invention relates to a light-emitting diode (LED), and particularly to an LED having optimized light-emitting efficiency and increased production yield.

### BACKGROUND OF THE INVENTION

FIG. 1 shows a conventional vertical LED. The conventional vertical LED includes a sandwich structure formed by an N-type semiconductor layer 1, a light-emitting layer 2 and a P-type semiconductor layer 3. Below the P-type semiconductor layer 3, a mirror layer 4, a tension release layer 5, a binding layer 6, a silicon substrate 7 and a P-type electrode 8 are disposed in sequence. A surface of the N-type semiconductor layer 1 is processed by a roughening treatment for increasing a light extraction rate. An N-type electrode 9 is further disposed on the roughened surface of the N-type semiconductor layer 1. By applying a voltage to the N-type electrode 9 and the P-type electrode 8, the N-type semiconductor layer 1 is enabled to provide electrons and the P-type semiconductor layer 3 is enabled to provide holes. Light is produced by the electrons and holes combining at the light-emitting layer 2.

FIG. 2 shows a detailed structure of the conventional tension release layer 5. The tension release layer 5 is formed by alternately stacking two blocking materials 5A and 5B made of two different materials selected from the group consisting of platinum, nickel, titanium, tungsten, copper, chromium, silicon and aluminum. The tension release layer 5 is mainly for releasing thermal stress and resisting against ion diffusion. The blocking materials 5A and 5B have a thermal expansion coefficient between those of the mirror layer 4 and the binding layer 6, and are thus capable of absorbing thermal stress generated from thermal expansion or contraction. Further, the blocking materials 5A and 5B, having a stable physical property and a high density, are also capable of blocking ion diffusion to prevent the LED from damages.

However, as the conventional tension release layer 5 is stacked by multiple layers of the blocking materials 5A and 5B, interface effect between the layers of the blocking materials 5A and 5B is easily generated. The interface effect generally generates piezoelectric effect to produce interface electric charges that undesirably affect and degrade the light-emitting efficiency of the LED. In addition, as being two different materials, the blocking materials 5A and 5B may mismatch each other to reduce a result of thermal stress release.

### SUMMARY OF THE INVENTION

Therefore, the primary object of the present invention is to provide a tension release layer structure of an LED that has matching layers without producing interface electric charges, thus is capable of eliminating interface effect to enhance light-emitting efficiency and increase production yield of the LED.

A tension release layer structure according to the present invention is applied to an LED which comprises a P-type electrode, a permanent substrate, a binding layer, a tension release layer, a mirror layer, a P-type semiconductor layer, a light-emitting layer, an N-type semiconductor layer and an N-type electrode that are stacked in sequence. The tension release layer is made of a complex material formed by at least two material elements with boundaries that are blended with each other.

Accordingly, the complex material in the tension release layer of the present invention does not have apparent interface separation, namely interface effect would not be generated between the material elements of the complex material in the tension release layer. Therefore, interface electric charges are prevented from generating in the tension release layer, thereby eliminating undesirable interface effect to enhance the light-emitting efficiency of the LED. Moreover, as mismatch between material elements is also eliminated by the blended boundaries thereof, production yield of the LED increases.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a conventional LED.

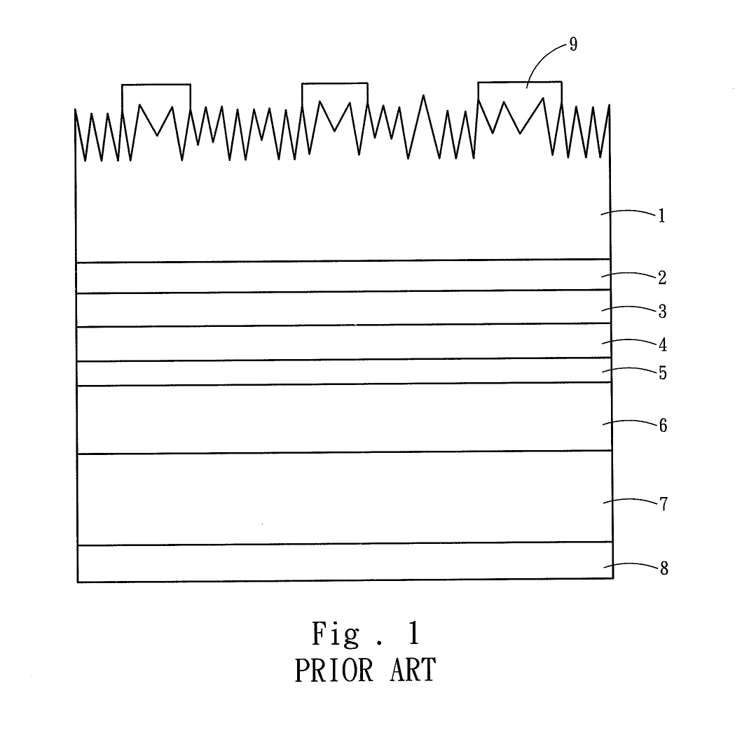

FIG. 2 is a schematic diagram of a conventional tension release layer.

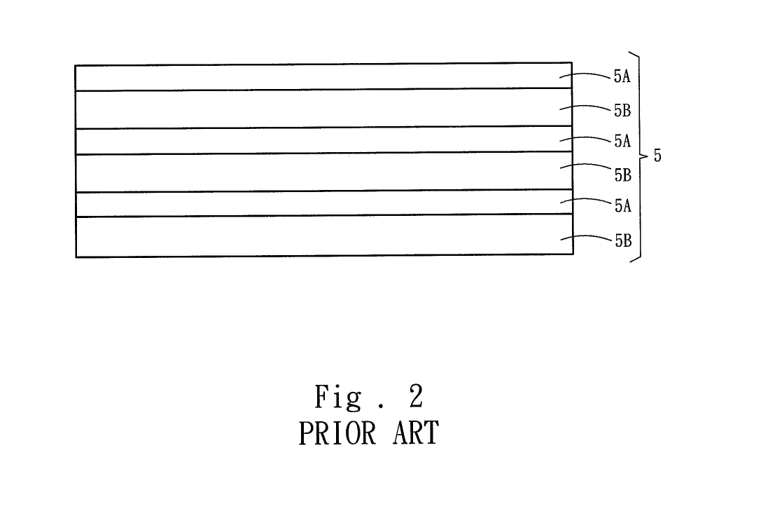

FIG. 3 is schematic diagram of a tension release layer structure applied to an LED according to one embodiment of the present invention.

FIG. 4 is a diagram of a first embodiment of the present invention.

FIG. 5 is a diagram showing component percentage according to a first embodiment of the present invention.

FIG. 6 is a diagram showing component percentage according to a second embodiment of the present invention.

### DETAILED DESCRIPTION OF THE PREFERRED EMBODIMENTS

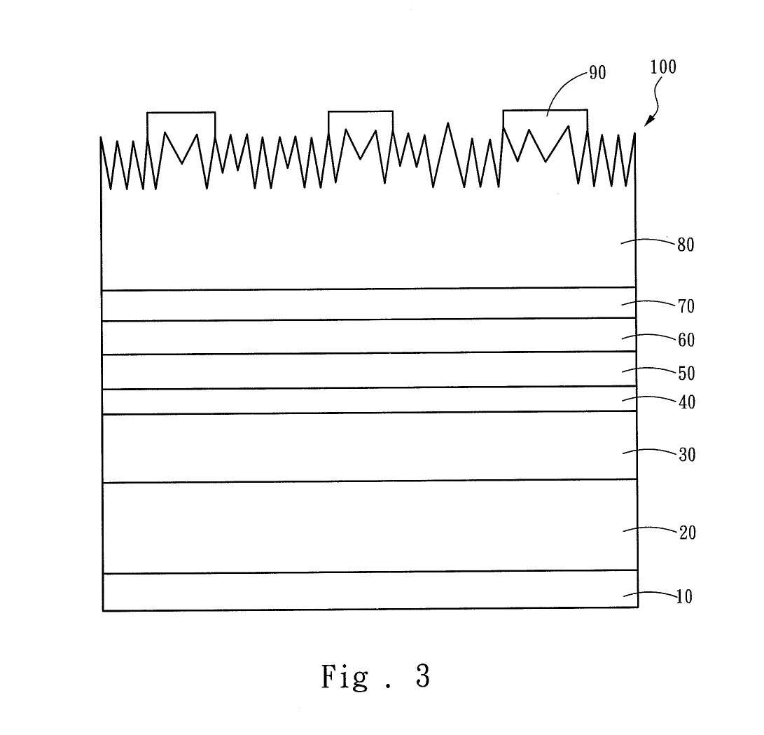

FIG. 3 shows a tension release layer structure of an LED according to one embodiment of the present invention. The tension release layer structure is applied to an LED 100 which comprises a P-type electrode 10, a permanent substrate 20, a binding layer 30, a tension release layer 40, a mirror layer 50, a P-type semiconductor layer 60, a light-emitting layer 70, an N-type semiconductor layer 80 and an N-type electrode 90 that are stacked in sequence.

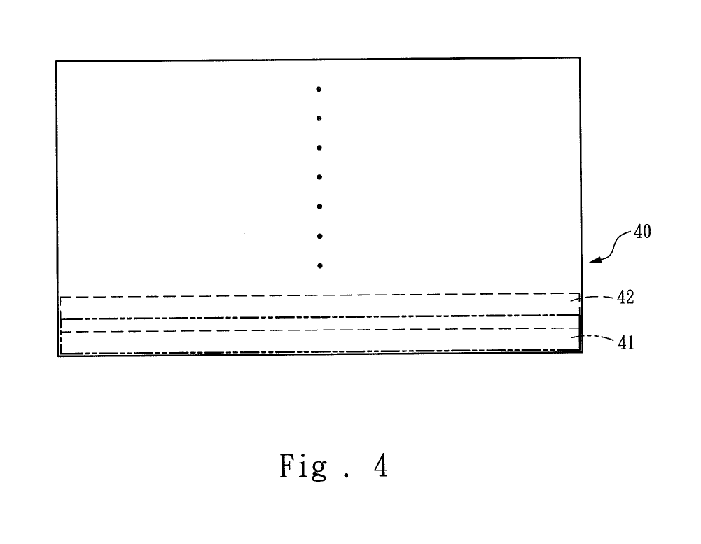

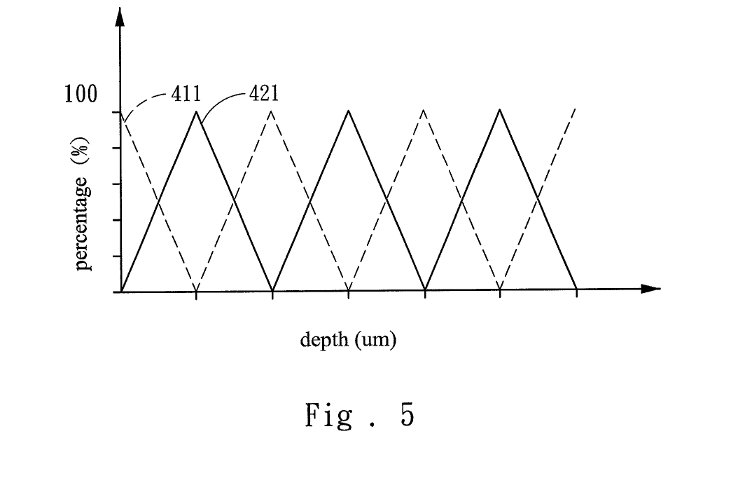

Referring to FIGS. 4 and 5, the tension release layer 40 of the present invention is made of a complex material formed by at least two material elements with boundaries that are blended with each other. For example, the tension release layer 40 comprises a first material layer 41 and a second material layer 42. To better explain a relationship between the first material layer 41 and the second material layer 42, the first material layer 41 and the second material layer 42 formed at the same depth in the tension release layer 40 have respectively a content percentage as a first material percentage 411 and a second material percentage 421. It should be noted that the first material layer 41 and the second material layer 42 do not have apparent interface separation, and the first material layer 41 and the second material layer 42 depicted in FIG. 4 are virtual interfaces but not physical interfaces.

Referring to FIG. 5, a transverse axle represents the depth of the tension release layer 40, a vertical axle represents the percentage, and two curves (respectively denoted in a dotted line and a solid line) respectively represent the first material percentage 411 and the second material percentage 421. In the present invention, the first material percentage 411 and the second material percentage 421 are complementary and gradually changed according to depth variation of the tension release layer 40. More specifically, a sum of the first material percentage 411 and the second material percentage 421 is a constant value (100%). For example, when the first material percentage is 50%, the second material percentage 421 is then 50%; when the first material percentage is 20%, the second material percentage 421 is then 80%; when the first material percentage 411 is 0%, the second material percentage 421 is then 100%.

A gradually changed range of the first material percentage 411 may be between a range of approaching 100% and approaching 0%, and the second material percentage 421 is changed according to the first material percentage 411 so that the sum of the two is a constant value (100%). Further, the first material percentage 411 is also changed according to the depth variation of the tension release layer 40, and may be gradually changed to and from between a range of approaching 100% and approaching 0% to form a multi-layer stacked structure. The tension release layer 40 (i.e., the first material layer 41 and the second material layer 42) may be formed by at least two materials selected from the group consisting of platinum, nickel, titanium, tungsten, chromium, aluminum, tungsten copper, titanium tungsten, tungsten silicide, nitride and silicon aluminum.

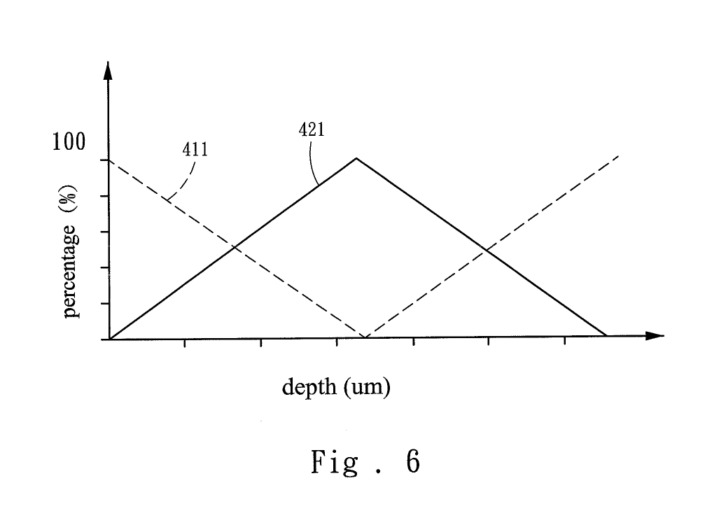

FIG. 6 shows a second embodiment of the present invention. It should be noted that unlike the multi-layer stacked structure in the first embodiment, the number of layers of the stacked structure does not need many, only if the boundaries of the material elements of the complex material in the tension release layer 40 are blended with each other, interface effect can be effectively prevented to otherwise generate interface electric charges. Therefore, the light-emitting efficiency of the LED is maintained, and mismatch between the material elements is also eliminated by the blended boundaries thereof, thereby increasing production yield of the LED.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

1. A tension release layer structure of a light-emitting diode (LED), the LED comprising a P-type electrode, a permanent substrate, a binding layer, a tension release layer, a mirror layer, a P-type semiconductor layer, a light-emitting layer, an N-type semiconductor layer and an N-type electrode that are stacked in sequence, the tension release layer structure being characterized in that:
the tension release layer is made of a complex material comprising a first material layer and a second material layer with boundaries that are blended with each other, the first material layer and the second material layer formed at the same depth in the tension release layer including respectively a first material percentage and a second material percentage, which are summed to a constant value of 100% and are complementary to each other and gradually change according to depth variation of the tension release layer.

2. (canceled)

3. The tension release layer structure of claim 1, wherein a gradually changed range of the first material percentage is between a range of approaching 100% and approaching 0%.

4. The tension release layer structure of claim 3, wherein the first material percentage is changed according to the depth variation of the tension release layer, and gradually changed to and fro between the range of approaching 100% and approaching 0%.

5. The tension release layer structure of claim 1, wherein the complex material of the tension release layer is selected from the group consisting of platinum, nickel, titanium, tungsten, chromium, aluminum, tungsten copper, titanium tungsten, tungsten suicide, nitride and silicon aluminum.

6. A light-emitting diode, comprising:
a P-type electrode;
a permanent substrate;
a tension release layer;
a mirror layer;
a P-type semiconductor layer;
a light-emitting layer;
an N-type semiconductor layer; and
an N-type electrode that are stacked in sequence,
wherein the tension release layer comprises a complex material comprising a first material layer and a second material layer with boundaries that are blended with each other, the first material layer and the second material layer formed at the same depth in the tension release layer including respectively a first material percentage and a second material percentage, which are summed to A constant value of 100% and are complementary to each other and gradually change according to depth variation of the tension release layer.
